(19) United States
(12) Patent Application Publication
(10) Pub. No.: US 2017/0162363 A1
(43) Pub. Date: Jun. 8, 2017

(54) STRUCTURE ANALYSIS METHOD USING A SCANNING ELECTRON MICROSCOPE

(71) Applicant: SAMSUNG ELECTRONICS CO., LTD., SUWON-SI (KR)

(72) Inventors: JIN KWAN KIM, SEONGNAM-SI (KR); MIN KOOK KIM, GOYANG-SI (KR); JUNG SOO KIM, HWASEONG-SI (KR); YU SIN YANG, SEOUL (KR); CHUNG SAM JUN, SUWON-SI (KR)

(21) Appl. No.: 15/286,678

(22) Filed: Oct. 6, 2016

(30) Foreign Application Priority Data
Dec. 7, 2015 (KR) 10-2015-0172999

(51) Int. Cl. H01J 37/22; H01J 37/28

(52) U.S. Cl. CPC H01J 37/222; H01J 37/28; H01J 2237/2803; H01J 2237/2804; H01J 2237/2806; H01J 2237/0473

(57) ABSTRACT

A structure analysis method using a scanning electron microscope includes irradiating a sample with an electron beam having a first landing energy to obtain a first image at a first depth of the sample and accelerating the electron beam to have a second landing energy higher than the first landing energy to obtain a second image at a second depth of the sample.

### CROSS-REFERENCE TO RELATED APPLICATION

This application claims priority under 35 U.S.C. §119 to Korean Patent Application No. 10-2015-0172999 filed on Dec. 7, 2015 in the Korean Intellectual Property Office, the disclosure of which is incorporated by reference herein in its entirety.

### TECHNICAL FIELD

The present inventive concept relates to a structure analysis method using a scanning electron microscope.

### DESCRIPTION OF THE RELATED ART

A scanning electron microscope (SEM) is an apparatus that produces images of a sample by scanning the sample with a focused beam of electrons. The electrons interact with atoms in the sample to generate second electrons or back-scattered electrons from the sample that contain information about the sample's surface topography and constitution.

Due to the miniaturization of a semiconductor process, the utilization of the SEM is increasing. For example, in semiconductor micro-processing, the surface state of a sample, in other words, the two-dimensional planar image of the sample, can be obtained using the SEM.

However, it may be not sufficient to analyze the structure of a sample including a semiconductor device through only the two-dimensional image of the sample.

### SUMMARY

According to an example embodiment of the inventive concept there is provided a structure analysis method using a scanning electron microscope, the structure analysis method comprises irradiating a sample with an electron beam having a first landing energy to obtain a first image at a first depth of the sample and accelerating the electron beam to have a second landing energy higher than the first landing energy to obtain a second image at a second depth of the sample.

According to an example embodiment of the inventive concept there is provided a structure analysis method using a scanning electron microscope, the structure analysis method comprises irradiating a sample with an electron beam, wherein the electron beam has a landing energy and penetrates the sample, accelerating the electron beam to increase the landing energy and obtaining a plurality of images corresponding to a plurality of depths in the sample, wherein the plurality of depths are reached by increasing the landing energy of the electron beam.

According to an example embodiment of the inventive concept there is provided a structure analysis method using a scanning electron microscope, the structure analysis method comprises scanning a sample with a first electron beam and measuring a first penetration depth, wherein the first electron beam has a first landing energy and penetrates the sample to the first penetration depth, scanning the sample with a second electron beam and measuring a second penetration depth, wherein the second electron beam has a second landing energy and penetrates the sample to the second penetration depth, measuring a first difference between the first landing energy and the second landing energy and a second difference between the first penetration depth and the second penetration depth, predicting a third landing energy capable of penetrating the sample to a third penetration depth, wherein the prediction is based on the first difference and the second difference, and obtaining an image of the third penetration depth using the third landing energy.

According to an example embodiment of the inventive concept, there is provided a structure analysis method using a scanning electron microscope comprising: irradiating a sample with a first electron beam having a first landing energy, wherein the sample is penetrated to a first depth by the first electron beam; irradiating the sample with a second electron beam having a second landing energy, wherein the sample is penetrated to a second depth by the second electron beam and the second depth is greater than the first depth; and identifying a change point in a gradient graph of signal electrons emitted from the application of the first and second electron beams as an interface between two different layers of the sample.

### BRIEF DESCRIPTION OF THE DRAWINGS

The above and other features of the present inventive concept will become more apparent by describing in detail example embodiments thereof with reference to the attached drawings, in which:

FIG. 1 is a diagram for illustrating a basic principle employed by structure analysis methods using a scanning electron microscope according to example embodiments of the present inventive concept.

FIG. 2 is a graph showing simulation results in silicon for illustrating the basic principle employed by structure analysis methods using a scanning electron microscope according to example embodiments of the present inventive concept.

FIG. 3 is a graph showing simulation results in silicon oxide for illustrating the basic principle employed by structure analysis methods using a scanning electron microscope according to example embodiments of the present inventive concept.

FIG. 4 is a flowchart illustrating a structure analysis method using a scanning electron microscope according to an example embodiment of the present inventive concept.

FIG. 5 is a cross-sectional view of a specific sample for illustrating a structure analysis method using a scanning electron microscope according to an example embodiment of the present inventive concept.

FIG. 6 is a graph showing the change of electronic signals with respect to the change of landing energy incident on the sample shown in FIG. 5.

FIG. 7 is a cross-sectional view of a specific sample for illustrating a structure analysis method using a scanning electron microscope according to an example embodiment of the present inventive concept.

FIG. 8 is a graph showing the change of electronic signals with respect to the change of landing energy incident on the sample shown in FIG. 7.

FIG. 9 is a flowchart illustrating a structure analysis method using a scanning electron microscope according to an example embodiment of the present inventive concept.

FIG. 10 is a flowchart illustrating a structure analysis method using a scanning electron microscope according to an example embodiment of the present inventive concept.

FIG. 11 shows a perspective view and a cross-sectional view of a sample for illustrating the structure analysis method using a scanning electron microscope according to an example embodiment of the present inventive concept.

FIG. 12 shows an image of a plurality of scanning electron microscopes for illustrating the structure analysis method using a scanning electron microscope according to an example embodiment of the present inventive concept.

FIG. 13 shows a perspective view and a cross-sectional view of a steric structure realized using the images of the plurality of scanning electron microscopes of FIG. 12.

FIG. 14 is a schematic view of a scanning electron microscope used in the structure analysis methods according to example embodiments of the present inventive concept.

### DETAILED DESCRIPTION OF THE EMBODIMENTS

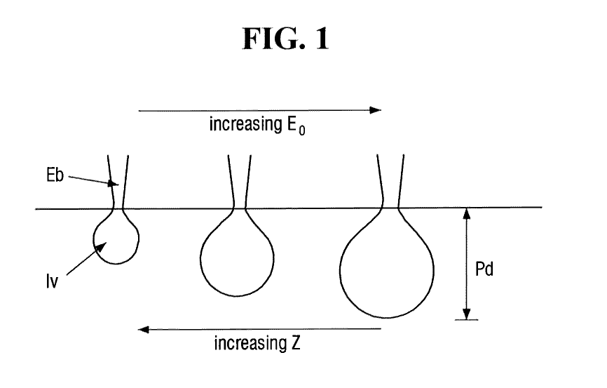

Hereinafter, a basic principle employed by structure analysis methods using a scanning electron microscope according to example embodiments of the present inventive concept will be described with reference to FIGS. 1 to 3.

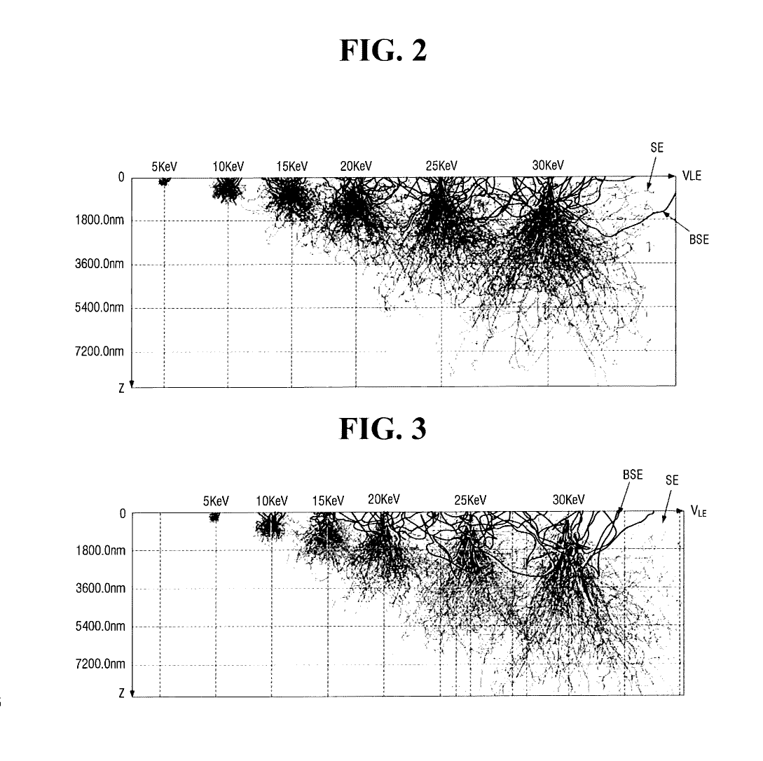

FIG. 1 is a diagram for illustrating a basic principle employed by structure analysis methods using a scanning electron microscope according to example embodiments of the present inventive concept. FIG. 2 is a graph showing simulation results in silicon for illustrating the basic principle employed by structure analysis methods using a scanning electron microscope according to example embodiments of the present inventive concept. FIG. 3 is a graph showing simulation results in silicon oxide for illustrating the basic principle employed by structure analysis methods using a scanning electron microscope according to example embodiments of the present inventive concept.

Referring to FIG. 1, Iv represents an interaction volume, and E₀ represents incident energy. Pd represents a penetration depth, Z represents an atomic number and Eb represents an electron beam.

Referring to FIG. 1, it can be ascertained that, as the incident energy E₀ increases, the interaction volume Iv gradually increases, and thus, the penetration depth Pd also increases. The incident energy E₀ is energy including the landing energy of an electron beam of a scanning electron microscope.

Therefore, the landing energy of an electron beam of a scanning electron microscope, represented by the incident energy E₀, is a major factor in determining the penetration depth Pd and the interaction volume Iv when the electron beam reaches a sample.

The penetration depth Pd of an electron having a landing energy as the incident energy E₀ is represented by the following Mathematical Formula 1.

ρR≈αEₒ^{r} [Formula 1]

Here, ρ represents the density (g/cm³) of the sample, R represents the penetration depth Pd, E₀ represents the incident energy (KeV), α represents a constant number of about 0.1, and r represents a constant number of about 1.35.

If the transmission distance of electrons is represented by ρR which is a product of ρ (density of sample) and R, α may be represented by a constant number independent of atomic mass. For example, in the case of carbon (Z=6) (ρ is about 2 g/cm³, and E₀ is about 10 KeV), the penetration depth Pd of electrons is about 1 and in the case of gold (Z=6) (ρ is about 20 g/cm³, and E₀ is about 10 KeV), the penetration depth Pd of electrons is about 0.2 μm.

The penetration depth Pd of electrons included in an electron beam correlates highly with the decrease in the number of electrons capable of being moved forward by back scattering, and the probability of high-angle elastic scattering occurring is proportional to the square (Z²) of the atomic number.

The transmission distance of electrons is also changed depending on the increase/decrease of the incident energy E₀. In the case of carbon, the transmission distance of electrons of 1 KeV decreases to a level of about 50 nm, and in the case of gold, the transmission distance thereof decreases to a level of about 10 nm.

In an example embodiment of the present inventive concept, a principle of penetrating a sample with an electron beam emitted from a scanning electron microscope by increasing the landing energy of the electron beam is used. The theoretical basis of the principle has been described above, and example embodiments of the present inventive concept using the principle will be described later.

FIG. 2 shows the simulation results for measuring the penetration depth Z of an electron beam incident on silicon (Si) depending on the variation of landing energy VLE of the electron beam. The simulation is a Monte-carlo simulation method, and the landing energy of the electron beam is sequentially increased in the order of 5 KeV, 10 KeV, 15 KeV, 20 KeV, 25 KeV and 30 KeV along the VLE axis. A plurality of complex lines appearing at each landing energy point represent the migration channels of back-scattered electrons BSE and secondary electrons SE in the silicon (Si).

More particularly, relatively dark lines represent the migration channels of the back-scattered electrons BSE, and relatively light lines represent the migration channels of the secondary electrons SE.

As shown in FIG. 2, it can be ascertained that, as the landing energy of the electron beam is sequentially increased in the order of 5 KeV, 10 KeV, 15 KeV, 20 KeV, 25 KeV and 30 KeV along the VLE axis, the penetration depth Z thereof is also gradually increased. In other words, as the landing energy of the electron beam increases, if the penetration depth Z of the electron beam into the sample increases, this phenomenon can be observed through the migration channels of the back-scattered electrons BSE and secondary electrons SE in the sample.

For example, it can be ascertained that, when the landing energy of the electron beam is 10 KeV (second energy of VLE axis), back-scattered electrons BSE and secondary electrons SE penetrating the silicon (Si) to a depth of 3600 nm or less scarcely exist, but, when the landing energy of the electron beam is 30 KeV (sixth energy of VLE axis), a very large number of back-scattered electrons BSE and secondary electrons SE penetrate the silicon (Si) to a depth of 3600 nm or less.

In other words, it can be ascertained that, the stronger the energy of the electron beam, the deeper the electron beam penetrates the silicon (Si).

FIG. 3 shows the simulation results for measuring the penetration depth Z of an electron beam incident on silicon oxide (SiO₂) depending on the variation of landing energy VLE of the electron beam. The simulation is a Monte-carlo simulation method, and the landing energy of the electron beam is sequentially increased in the order of 5 KeV, 10 KeV, 15 KeV, 20 KeV, 25 Key and 30 KeV along the VLE axis. A plurality of complex lines appearing at each landing energy point represent the migration channels of back-scattered electrons BSE and secondary electrons SE in the silicon oxide (SiO₂).

More particularly, relatively dark lines represent the migration channels of the back-scattered electrons BSE, and relatively light lines represent the migration channels of the secondary electrons SE.

As shown in FIG. 3, it can be ascertained that, as the landing energy of the electron beam is sequentially increased in the order of 5 KeV, 10 KeV, 15 KeV, 20 KeV, 25 KeV and 30 KeV along the VLE axis, the penetration depth Z thereof is also gradually increased.

For example, it can be ascertained that, when the landing energy of the electron beam is 10 KeV (second energy of VLE axis), back-scattered electrons BSE and secondary electrons SE penetrating the silicon oxide (SiO₂) to a depth of 1800 nm or less scarcely exist, but, when the landing energy of the electron beam is 30 KeV (sixth energy of VLE axis), a very large number of back-scattered electrons BSE and secondary electrons SE penetrate the silicon oxide (SiO₂) to a depth of 1800 nm or less.

As can be ascertained from FIGS. 1 to 3, although the penetration depth of the electron beam is changed depending on the material constituting the sample, the electron beam can more deeply penetrate the sample when the electron beam includes electrons having high energy. Moreover, due to the penetration of the electron beam, signal electrons discharged to the outside, in other words, back-scattered electrons BSE and secondary electrons SE, are collected, and the difference in the internal configuration of the sample due to the difference in the material constituting the sample can be imaged using the collected signal electrons.

In other words, when the difference in the internal configuration of the sample is caused by the difference in the material constituting the sample, a position that the electron beam penetrates can be imaged based on the information about the difference in the material constituting the sample at the position.

Among the signal electrons, the back-scattered electrons BSE are electrons introduced into the sample and scattered and discharged at an angle of 90° or more. In this case, electrons having a scattering angle of 90° or less may collide with each other in the sample several times and then may be discharged to the outside. In addition, electrons having a scattering angle of 90° or less may be discharged to the outside in the form of a small energy variation and a large momentum difference through elastic scattering. Since high-angle elastic scattering is proportional to the square of the atomic number as described above, the information associated with the atomic number can be obtained from the image obtained based on the back-scattered electrons BSE.

Further, in an example embodiment of the present inventive concept, the signal electrons, in other words, the back-scattered electrons BSE and secondary electrons SE are discharged from one point in the sample. Therefore, the back-scattered electrons BSE and secondary electrons SE discharged from the inside to the outside of the sample collide with the inside of the sample, and thus may be converted to another form.

Accordingly, in an example embodiment of the present inventive concept, to determine the internal structure of the sample depending on the change of landing energy, a process of obtaining as many as possible of the back-scattered electrons BSE and secondary electrons SE discharged from the inside to the outside of the sample is performed.

Thus, it is possible to increase the resolution of an image obtained from the signal electrons in the sample. However, the present inventive concept is not limited thereto. For example, the present inventive concept can be realized when specific signal electrons are obtained as long as the information about the inside of the sample can be obtained by obtaining any one of the back-scattered electrons BSE and the secondary electrons SE.

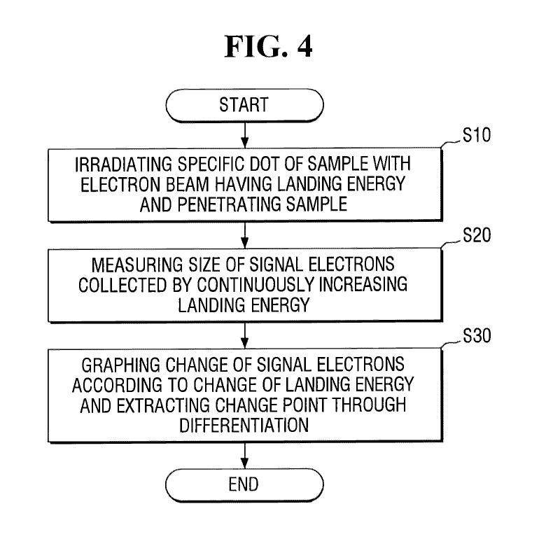

Hereinafter, a structure analysis method using a scanning electron microscope according to an example embodiment of the present inventive concept will be described with reference to FIGS. 4 to 8.

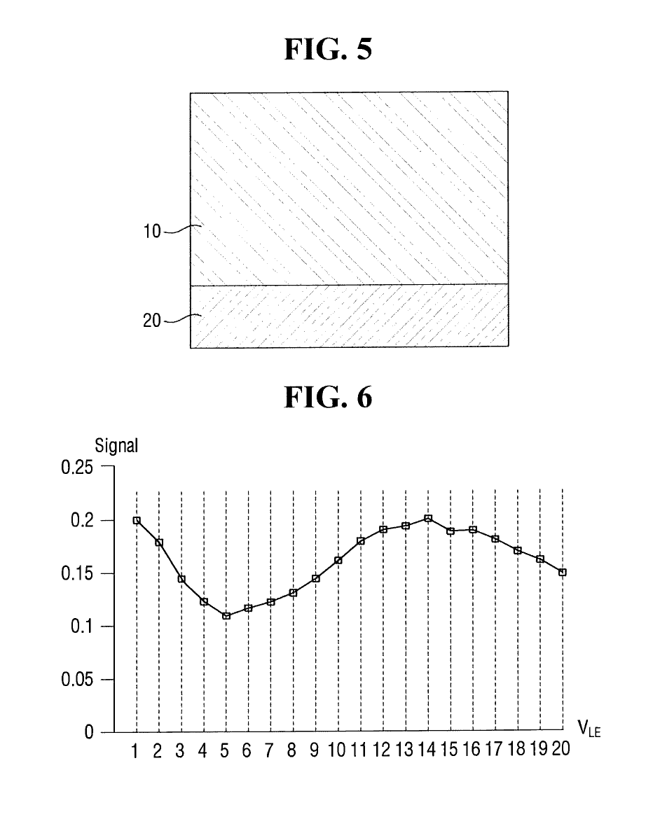

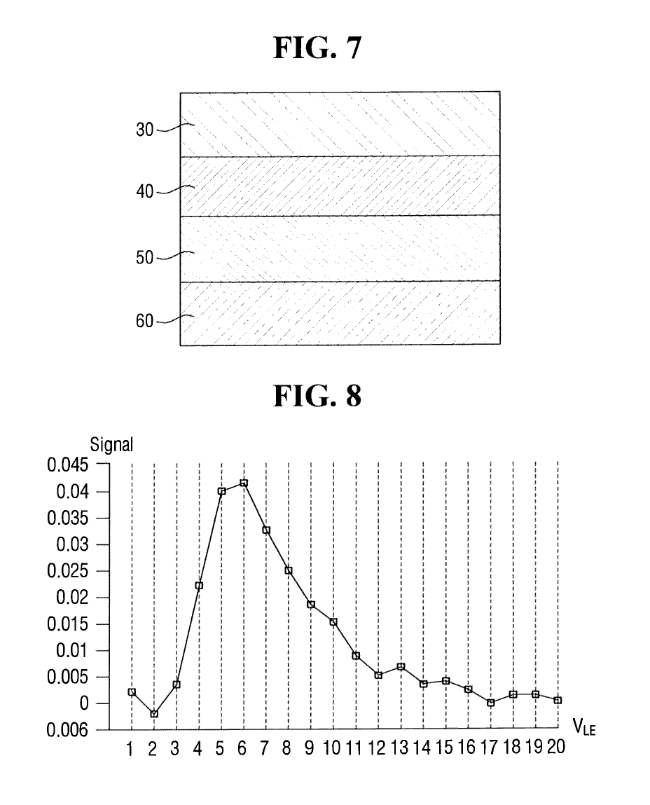

FIG. 4 is a flowchart illustrating a structure analysis method using a scanning electron microscope according to an example embodiment of the present inventive concept. FIG. 5 is a cross-sectional view of a specific sample for illustrating the structure analysis method using a scanning electron microscope according to an example embodiment of the present inventive concept. FIG. 6 is a graph showing the change of electronic signals with respect to the change of landing energy incident on the sample shown in FIG. 5. FIG. 7 is a cross-sectional view of a specific sample for illustrating a structure analysis method using a scanning electron microscope according to an example embodiment of the present inventive concept. FIG. 8 is a graph showing the change of electronic signals with respect to the change of landing energy incident on the sample shown in FIG. 7.

Referring to FIG. 4, the structure analysis method using a scanning electron microscope according to an example embodiment of the present inventive concept includes the steps of: (S10) irradiating a specific dot of a sample with an electron beam having a landing energy and penetrating the sample; (S20) measuring the size of signal electrons collected by the continuous irradiation of the landing energy; and (S30) graphing the change of the signal electrons according to the change of the landing energy and extracting a change point through differentiation.

In the present example embodiment, an electron beam emitted from a scanning electron microscope is applied to a specific dot of a sample. Subsequently, as the landing energy of the electron beam increases, as described with reference to FIGS. 1 to 3, the electron beam can penetrate the sample more deeply.

In other words, the scanning electron microscope can obtain information of a line unit according to a depth direction, in other words, information of the change of an internal structure according to a vertical direction, through the electron beam incident in a dot unit. This means that information of a line unit is obtained through information of a plurality of dot units.

In the electron beam gradually penetrating into the sample in a dot unit, emitted signal electrons may have different characteristics when the composition of the internal material disposed in the sample is changed. In other words, when the composition of the internal material is constant, the emitted signal electrons are not greatly changed. However, when the composition of the internal material is changed, the intensity or the like of the emitted signal electrons is greatly changed. Thus, the change of the internal material of a sample, for example, the location of an interface, in the case where the sample has a multi-layered structure, can be determined.

Hereinafter, the structure analysis method using a scanning electron microscope according to the present example embodiment will be described in more detail with reference to FIGS. 5 to 8.

Referring to FIG. 5, the cross-section of a sample having a two-layered laminate structure can be seen. Here, the lower layer may be a silicon layer 20, and the upper layer may be a silicon oxide layer 10.

Referring to FIG. 6, it can be ascertained that the collected electronic signals are changed with the increase of landing energy VLE. Here, the landing energy VLE has a unit of KeV, and the electronic signals mean intensity and do not have a specific unit.

Referring to FIG. 6 again, it can be ascertained that the electronic signals decrease at a predetermined gradient when the landing energy VLE increases from 1 KeV to 5 KeV. Since the electron beam is not yet introduced into the sample of FIG. 5 at the time of the initial increase of the landing energy VLE, information about an inner image is not disclosed.

Subsequently, it can be ascertained that the electronic signals increase at a predetermined gradient when the landing energy VLE increases from 5 KeV to 14 KeV. Further, it can be ascertained that the electron beam penetrates into the sample of FIG. 5 when the landing energy VLE is 5 KeV.

Subsequently, it can be ascertained that the electronic signals decrease at a predetermined gradient when the landing energy VLE increases from 14 KeV to 20 KeV. Particularly, it can be ascertained that the gradient of the graph is changed when the landing energy VLE is 14 KeV. The change point of the gradient of the graph can be extracted by the differentiation of the gradient of the graph. Further, it can be ascertained from the graph that the electron beam emitted from the scanning electron microscope penetrates the interface between the silicon layer 20 and the silicon oxide layer 10.

In other words, in the present example embodiment, through the process of continuously obtaining the information of a specific sample in a dot unit in the depth direction of the sample, it can be ascertained whether the sample has a multi-layered structure or whether the sample has several layers if it has a multi-layered structure. Moreover, in the case where the sample has a multi-layered structure, the thickness of each layer can be observed.

Subsequently, referring to FIGS. 7 and 8, a case of a sample having a four-layered structure will be described.

Referring to FIG. 7, the cross-section of a sample having a four-layered structure can be seen. The sample includes a silicon layer 60, a polysilicon layer 50, a silicon nitride layer 40, and a silicon oxide layer 30.

Subsequently, it is ascertained whether the structure of FIG. 7 can be analyzed by the graph of FIG. 8.

The graph of FIG. 8, similarly to the graph of FIG. 6, shows the change of electronic signals in the case where the electron beam emitted from the scanning electron microscope is incident on the specific dot of the upper surface of the silicon oxide layer 30 of FIG. 7 and the landing energy VLE of the electron beam is increased at a predetermined gradient.

First, it can be ascertained that the electronic signals decrease when the landing energy VLE increases 1 KeV to 2 KeV. This means that the landing energy VLE of the electron beam is not yet sufficient to penetrate into the silicon oxide layer 30.

Subsequently, it can be ascertained that the electronic signals increase when the landing energy VLE increases from 2 KeV to 6 KeV, and then, the electronic signals decrease when the landing energy VLE is 6 KeV. Thus, it can be ascertained that the electron beam penetrates the interface between the silicon nitride layer 40 and the silicon oxide layer 30.

Subsequently, it can be ascertained that the electronic signals continuously decrease with the increase of the landing energy VLE, and then, the electronic signals increase again when the landing energy VLE is 12 KeV. Thus, it can be ascertained that the electron beam penetrates the interface between the silicon nitride layer 40 and the polysilicon layer 50.

Subsequently, it can be ascertained that the increasing electronic signals decrease again when the landing energy VLE is 13 KeV. Thus, it can be ascertained that the electron beam penetrates the interface between the polysilicon layer 50 and the silicon layer 60.

The structure analysis method using a scanning electron microscope according to the present example embodiment can analyze the number of layers included in the sample by sequentially increasing the landing energy of the electron beam of the scanning electron microscope. This may occur even when it is not known whether the sample has a multi-layered structure.

Moreover, this structure analysis method can determine the thickness of each of the layers included in the sample. For example, from FIG. 8, it can be ascertained that the silicon nitride layer 40 and the silicon oxide layer 30 are relative thick, and the silicon layer 60 and the polysilicon layer 50 are relatively thin.

In the above described example embodiments, a case that the sample includes two layers and a case that the sample includes four layers have been described. However, the present inventive concept is not limited thereto. For example, samples with three or more than four layers may analyzed in accordance with an example embodiment of the present inventive concept.

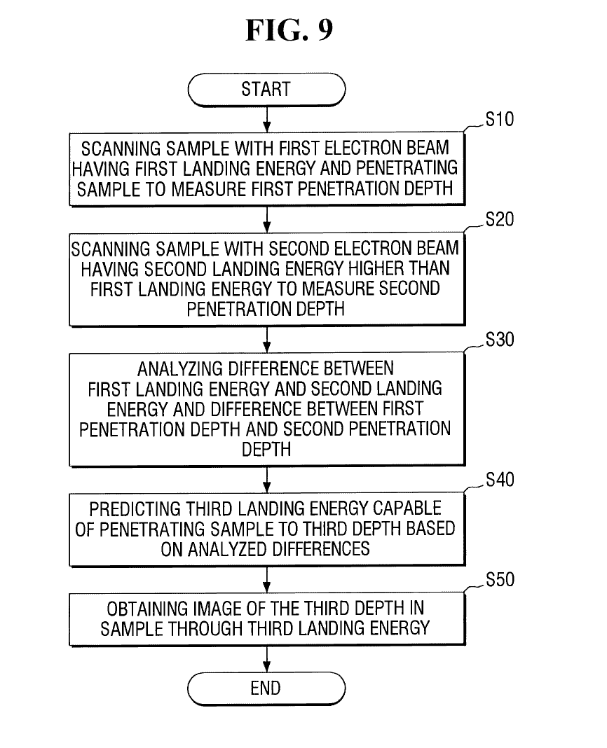

Next, a structure analysis method using a scanning electron microscope according to an example embodiment of the present inventive concept will be described with reference to FIG. 9.

FIG. 9 is a flowchart illustrating a structure analysis method using a scanning electron microscope according to an example embodiment of the present inventive concept.

Referring to FIG. 9, the structure analysis method using a scanning electron microscope according to an example embodiment of the present inventive concept includes the steps of: (S10) scanning a sample with a first electron beam having a first landing energy and penetrating the sample to measure a first penetration depth; (S20) scanning the sample with a second electron beam having a second landing energy higher than the first landing energy to measure a second penetration depth; (S30) analyzing a first difference between the first landing energy and the second landing energy and a second difference between the first penetration depth and the second penetration depth; (S40) predicting a third landing energy capable of penetrating the sample to a third depth, based on the analysis of the first difference and the second difference; and (S50) obtaining an image of the third depth in the sample through the third landing energy.

In other words, in the present example embodiment, the penetration distance of the electron beam into the sample is calculated depending on the size of the landing energy of the electron beam, and then, an image in the specific depth of the sample can be obtained based on the calculated penetration distance.

In the step (S10) of scanning a sample with a first electron beam having a first landing energy and penetrating the sample to measure a first penetration depth, both the irradiation of a specific dot with the first electron beam and the scanning of a predetermined plane with the first electron beam may be included.

In the step (S20) of scanning the sample with a second electron beam having a second landing energy higher than the first landing energy to measure a second penetration depth, both the irradiation of a specific dot with the second electron beam and the scanning of a predetermined plane with the second electron beam may be included.

In the step (S30) of analyzing a first difference between the first landing energy and the second landing energy and a second difference between the first penetration depth and the second penetration depth, the analysis is based on steps 10 and 20 (S10 and S20). In other words, the change of the penetration depth depending on the change of the landing energy may be calculated by the steps 10 and 20 (S10 and S20).

In the step (S40) of predicting a third landing energy capable of penetrating the sample to a third depth based on the analysis of the first difference and the second difference, the third landing energy necessary for penetrating the sample to the third depth as a target depth can be calculated or predicted based on the analysis obtained by the change of the penetration depth depending on the change of the landing energy.

Finally, in the step (S50) of obtaining an image of the third depth in the sample through the third landing energy, the image of the third depth in the sample can be obtained through the third landing energy.

In the present example embodiment, in the case where the sample has a structure containing a single material, when voids are repeatedly formed at predetermined depths, defects in the sample can be easily observed by the structure analysis method using a scanning electron microscope according to the present example embodiment.

Further, even in the case where the sample has a multi-layered structure, if the information about the change of the penetration distance in the multi-layered structure depending on the change of the landing energy is previously known, the defects in the sample can also be easily observed by using the present example embodiment.

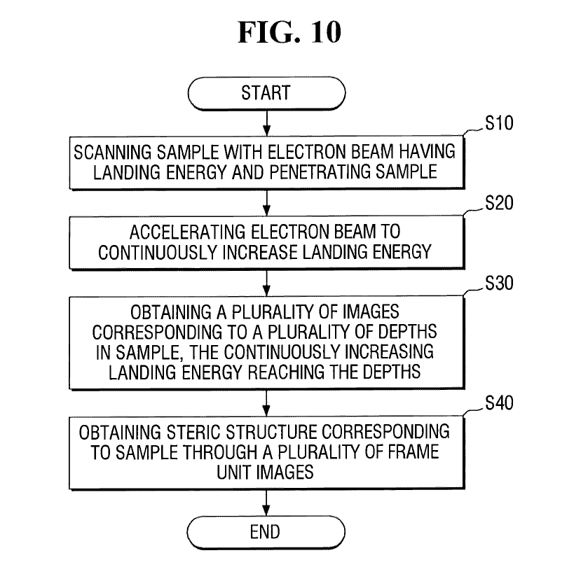

Next, a structure analysis method using a scanning electron microscope according to an example embodiment of the present inventive concept will be described with reference to FIGS. 10 to 13.

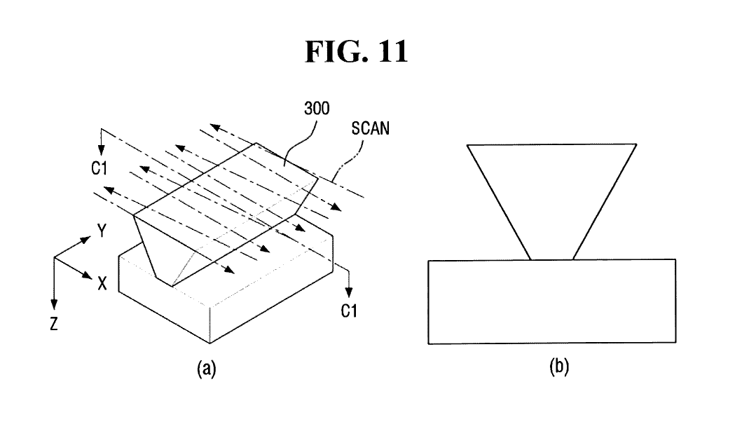

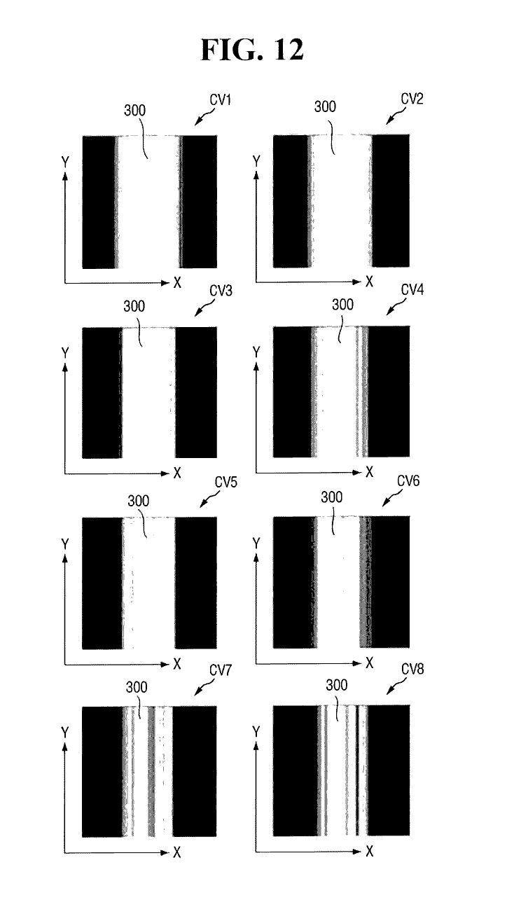

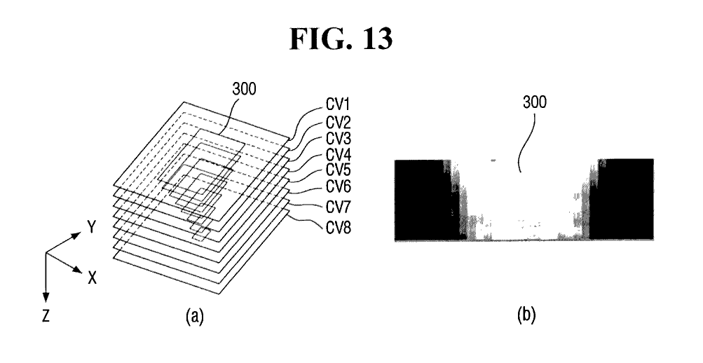

FIG. 10 is a flowchart illustrating a structure analysis method using a scanning electron microscope according to an example embodiment of the present inventive concept. FIG. 11 shows a perspective view and a cross-sectional view of a sample for illustrating the structure analysis method using a scanning electron microscope according to an example embodiment of the present inventive concept. FIG. 12 shows the image of a plurality of scanning electron microscopes for illustrating the structure analysis method using a scanning electron microscope according to an example embodiment of the present inventive concept. FIG. 13 shows a perspective view and a cross-sectional view of a steric structure realized using the images of the plurality of scanning electron microscopes of FIG. 12.

Referring to FIG. 10, the structure analysis method using a scanning electron microscope according to an example embodiment of the present inventive concept includes the steps of: (S10) scanning a sample with an electron beam having a landing energy and penetrating the sample; (S20) accelerating the electron beam to continuously increase the landing energy; (S30) obtaining a plurality of frame unit images corresponding to a plurality of depths in the sample; and (S40) obtaining a steric structure corresponding to the sample through the plurality of frame unit images.

The structure analysis method using a scanning electron microscope according to the present example embodiment will be described in more detail with reference to FIGS. 11 to 13.

Referring to FIG. 11, to explain the structure analysis method using a scanning electron microscope of FIG. 10, FIG. 11A shows a perspective view of a sample 300, and FIG. 11B shows a cross-sectional view of the sample 300 taken along line C1-C1 of FIG. 10.

Referring to FIGS. 10 and 11, the sample 300 is scanned with an electron beam Eb having a landing energy and penetrating the sample 300 (S10). The electron beam Eb is emitted from a scanning electron microscope. The scanning may be conducted in a first direction Y and a second direction X along the arrows represented by dotted lines as shown in FIG. 11A to apply the electron beam Eb onto one frame of the sample 300.

It is to be understood that although a case of scanning one frame of the sample 300 with the electron beam Eb has been described, the present inventive concept is not limited thereto. For example, the electron beam may also be applied to one dot of the sample 300.

First, it can be ascertained from FIG. 11A that the sample 300 has a trapezoidal pillar shape, and it can be ascertained from FIG. 11B that the cross-section of the sample 300 has an inverted trapezoidal shape.

Subsequently, the electron beam Eb is accelerated to continuously increase the landing energy (S20), and then, the plurality of frame unit images corresponding to a plurality of depths in the sample 300 are obtained (S30).

As described with reference to FIGS. 1 to 3, as the landing energy of the electron beam Eb increases, the penetration depth of the electron beam Eb into the sample 300 along a third direction Z increases. When the landing energy continuously increases, the penetration depth of the electron beam Eb into the sample 300 also increases, electronic signals are emitted from each depth, and a plurality of frame unit images can be obtained using the electronic signals. Further, as described above, the electronic signals may include back-scattered electrons BSE and secondary electrons SE, but the present inventive concept is not limited thereto. For example, the electronic signals may further include auger electrons.

FIG. 12 shows the plurality of frame unit images obtained by the method just described with reference to FIGS. 10 and 11. Referring to FIG. 12, a first image CV1 may be an image obtained from a first depth from the surface of the sample 300. A second image CV2 may be an image obtained from a second depth deeper than the first depth from the surface of the sample 300.

A third image CV3 may be an image obtained from a third depth deeper than the second depth from the surface of the sample 300. A fourth image CV4 may be an image obtained from a fourth depth deeper than the third depth from the surface of the sample 300.

A fifth image CV5 may be an image obtained from a fifth depth deeper than the fourth depth from the surface of the sample 300. A sixth image CV6 may be an image obtained from a sixth depth deeper than the fifth depth from the surface of the sample 300.

A seventh image CV7 may be an image obtained from a seventh depth deeper than the sixth depth from the surface of the sample 300. An eighth image CV8 may be an image obtained from an eighth depth deeper than the seventh depth from the surface of the sample 300. All of the first to eighth images CV1 to CV8, as shown in FIG. 12, may be frame unit images.

Referring to FIG. 12 again, it can be ascertained that the width of the sample 300 decreases as the depths of the first to eighth images CV1 to CV8 increase. The reason for this, as shown in FIG. 11, is that the cross-section of the sample 300 has an inverted trapezoidal shape.

Referring to FIG. 13, FIG. 13A shows a steric structure laminated with the first to eighth images CV1 to CV8, and FIG. 13B is the cross-sectional view of the steric structure of FIG. 13A.

In other words, the steric structure corresponding to the sample of FIG. 11 can be obtained through the plurality of frame unit images (S40). Comparing the perspective view (FIG. 13A) and cross-sectional view (FIG. 13B) of the steric structure of FIG. 13 with the perspective view (FIG. 11A) and cross-sectional view (FIG. 11B) of the sample 300 of FIG. 11, it can be ascertained that their shapes correspond to each other.

In the present example embodiment, the frame unit images in the sample are continuously obtained by continuously increasing the landing energy of the electron beam. This way, the steric structure corresponding to the sample is obtained by laminating the frame unit images in response to the determined depths of the sample, thereby facilitating analysis of the structure of the sample.

Through the structure analysis method using a scanning electron microscope according to the present example embodiment, the internal structure and three-dimensional steric structure of the sample can be obtained. Further, since this method uses a scanning electron microscope, the three-dimensional steric structure of the sample can be obtained relatively easily and rapidly.

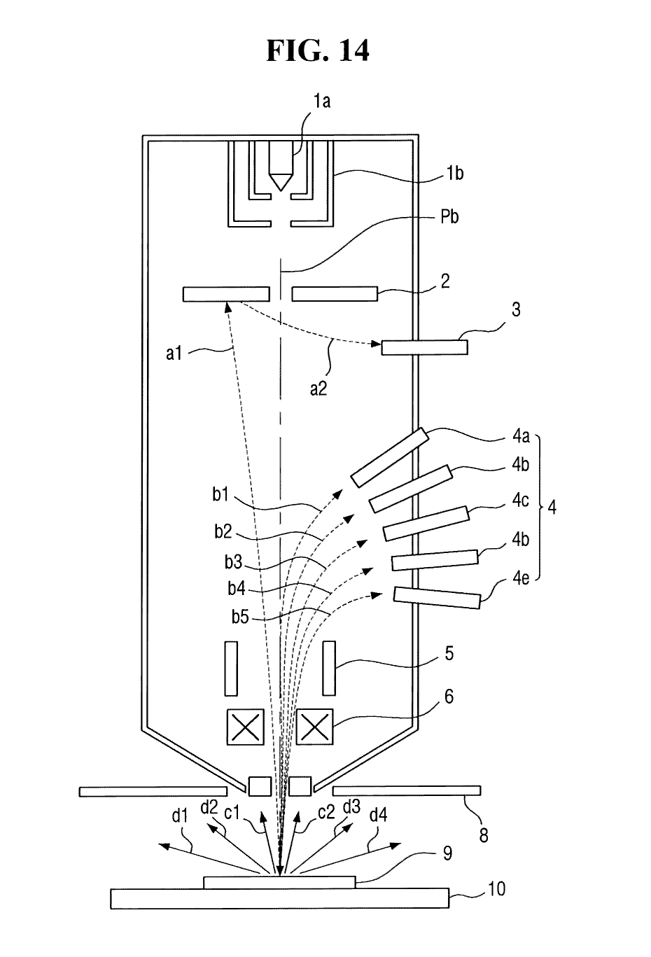

Subsequently, a scanning electron microscope used in the structure analysis methods according to example embodiments of the present inventive concept will be described in detail with reference to FIG. 14.

FIG. 14 is a schematic view of a scanning electron microscope used in the structure analysis methods according to example embodiments of the present inventive concept.

The scanning electron microscope includes a gun la for emitting an electron beam Pb and an accelerating voltage lb for supporting the variable operation of landing energy (V_{LE}) of the electron beam Pb.

Further, the scanning electron microscope includes a lens system 6 for adjusting the bias of a sample 9 disposed on a chuck 10a and controlling the position of the electron beam Pb.

Further, the scanning electron microscope includes a first detector 2, a second detector 3, a multiple angle detector system 4, a third detector 7, and a fourth detector 8 to separate and obtain electronic signals a1, a2, b1, b2, b3, b4, b5, c1, c2, d1, d2, d3, and d4 according to their characteristics.

In addition, in accordance with an example embodiment of the present inventive concept, the scanning electron microscope includes an energy splitter 5 and the multiple angle detector system 4 for obtaining each energy band to perform a detailed energy separation.

In other words, electronic signals b1, b2, b3, b4, and b5 passing through the energy splitter 5 can be classified by the energy splitter 5 according to their respective intensity of energy, and can be obtained by first to fifth angle detectors 4a, 4b, 4c, 4d, and 4e corresponding to the intensity thereof. For example, the energy splitter 5 can apply an electric field to the electronic signals b1, b2, b3, b4, and b5 passing through the energy splitter 5, and these electronic signals b1, b2, b3, b4, and b5 can be classified by the electric field according to their own energy characteristics (e.g., intensity and charge amount). The classified electronic signals b1, b2, b3, b4, and b5 can be respectively obtained by the first to fifth multiple angle detectors 4a, 4b, 4c, 4d, and 4e corresponding to their own characteristics.

In addition, although it is shown in FIG. 14 that the multiple angle detector system 4 includes five angle detectors, the number of the angle detectors is not limited thereto. For example, the multiple angle detector system 4 may include two to ten angle detectors.

In addition, the third and fourth angle detectors 7 and 8 separate and obtain the electronic signals according to the emission angle thereof. In this case, the third angle detector 7 can obtain the electronic signals emitted at a narrow angle, and the fourth angle detector 8 can obtain the electronic signals emitted at a relatively wide angle.

Since the scanning electron microscope according to the present example embodiment includes the energy splitter 5 and the multiple angle detector system 4 for acquiring each energy band, information about a three-dimensional steric structure proportional to the penetration depth of electrons can be obtained through the change of landing energy. Therefore, structure analysis proportional to the energy of electronic signals can be performed.

An example embodiment of the present inventive concept provides a structure analysis method using a scanning electron microscope, which can analyze the structure of a sample.

An example embodiment of the present inventive concept provides a structure analysis method using a scanning electron microscope, which can increase reliability.

An example embodiment of the present inventive concept provides a structure analysis method using a scanning electron microscope, which can increase the structure analysis speed of a sample while preventing the sample from being damaged.

An example embodiment of the present inventive concept provides a structure analysis method using a scanning electron microscope, which can obtain the three-dimensional image of a sample.

An example embodiment of the present inventive concept provides a structure analysis method using a scanning electron microscope, which can obtain the three-dimensional image of a sample by changing the landing energy of a scanning electron beam.

While the present inventive concept has been particularly shown and described with reference to example embodiments thereof, it will be understood by those of ordinary skill in the art that various changes in form and details may be made therein without departing from the spirit and scope of the present inventive concept as defined by the following claims.

1. A structure analysis method using a scanning electron microscope, comprising:
irradiating a sample with an electron beam having a first landing energy to obtain a first image at a first depth of the sample; and
accelerating the electron beam to have a second landing energy higher than the first landing energy to obtain a second image at a second depth of the sample.

2. The structure analysis method of claim 1,
wherein the irradiating of the sample with the electron beam includes scanning the sample along two-dimensional coordinates.

3. The structure analysis method of claim 2,
wherein the first image is a frame unit image obtained at the first depth, and the second image is a frame unit image obtained at the second depth; and
the method further includes obtaining a three-dimensional image using the first and second images.

4. The structure analysis method of claim 3,
wherein the obtaining of the three-dimensional image includes laminating the first and second images to correspond to the first and second depths.

5. The structure analysis method of claim 1,
wherein the first and second images are images obtained by collecting electronic signals emitted from the sample by the electron beam applied to the sample.

6. The structure analysis method of claim 5,
wherein the first image is a dot unit image at the first depth, and the second image is a dot unit image at the second depth; and
the method further includes measuring a change of the electronic signals using the first and second images and analyzing a change of the material constituting the sample at the first and second depths.

7. The structure analysis method of claim 5,
wherein the electronic signals include back-scattered electrons and secondary electrons.

8. A structure analysis method using a scanning electron microscope, comprising:
irradiating a sample with an electron beam, wherein the electron beam has a landing energy and penetrates the sample;
accelerating the electron beam to increase the landing energy; and
obtaining a plurality of images corresponding to a plurality of depths in the sample, wherein the plurality of depths are reached by increasing the landing energy of the electron beam.

9. The structure analysis method of claim 8,
wherein the irradiating of the sample with the electron beam includes scanning the sample along two-dimensional coordinates.

10. The structure analysis method of claim 9,
wherein the plurality of images are frame unit images respectively obtained at one of the plurality of depths.

11-13. (canceled)

14. The structure analysis method of claim 9, further comprising:
analyzing a change of the material constituting the sample according to a change of a gradient of the signal electrons.

15. The structure analysis method of claim 14,
wherein the analyzing of the change of the material constituting the sample includes extracting a change point corresponding to a difference of the gradient,

16. The structure analysis method of claim 8,
wherein the obtaining of the plurality of images includes collecting electronic signals emitted from the sample due to the electron beam applied to the sample.

17. The structure analysis method of claim 16,
wherein the electronic signals include back-scattered electrons and secondary electrons.

18. A structure analysis method using a scanning electron microscope, comprising:
scanning a sample with a first electron beam and measuring a first penetration depth, wherein the first electron beam has a first landing energy and penetrates the sample to the first penetration depth;
scanning the sample with a second electron and measuring a second penetration depth, wherein the second electron beam has a second landing energy and penetrates the sample to the second penetration depth;
measuring a first difference between the first landing energy and the second landing energy and a second difference between the first penetration depth and the second penetration depth;
predicting a third landing energy capable of penetrating the sample to a third penetration depth, wherein the prediction is based on the first difference and the second difference; and
obtaining an image of the third penetration depth using the third landing energy.

19-20. (canceled)

21. A structure analysis method using a scanning electron microscope, comprising:
irradiating a sample with a first electron beam having a first landing energy, wherein the sample is penetrated to a first depth by the first electron beam;
irradiating the sample with a second electron beam having a second landing energy, wherein the sample is penetrated to a second depth by the second electron beam and the second depth is greater than the first depth; and
identifying a change point in a gradient graph of signal electrons emitted from the application of the first and second electron beams as an interface between two different layers of the sample.

22. The structure analysis method of claim 21, further comprising constructing a three dimensional image including a first image of the sample at the first depth and a second image of the sample at the second depth.

23. The structure analysis method of claim 21, wherein the emitted signal electrons include back scattered electrons and secondary electrons.

24. The structure analysis method of claim 21, wherein he sample is irradiated with the first and second electron beams in first and second directions.

25. The structure analysis method of claim 21, wherein the second electron beam has a greater landing energy than the first electron beam.
